(19) United States
(12) Patent Application Publication
(10) Pub. No.: US 2020/0194631 A1
(43) Pub. Date: Jun. 18, 2020

(54) Method for Producing a Light-Emitting Semiconductor Device and Light-Emitting Semiconductor Device

(71) Applicant: OSRAM Opto Semiconductors GmbH, Regensburg (DE)

(72) Inventors: Darshan Kundaliya, Middleton, MA (US); Madis Raukas, Lexington, MA (US)

(21) Appl. No.: 16/220,158

(22) Filed: Dec. 14, 2018

(51) Int. Cl. H01L 33/50; H01L 33/00; H01L 33/06; H01L 33/26; H01L 31/055

(52) U.S. Cl. CPC H01L 33/502; H01L 33/005; H01L 2933/0041; H01L 33/26; H01L 31/055; H01L 33/06

(57) ABSTRACT

A method for producing a light-emitting semiconductor device and a light-emitting semiconductor device are disclosed. In an embodiment, a method for producing a light-emitting semiconductor device includes providing a growth substrate that is transmissive for visible light; and growing a semiconductor layer sequence on the growth substrate, wherein the semiconductor layer sequence is based on InGaAlP, and wherein the semiconductor layer sequence comprises a multi-quantum well structure configured to absorb blue light or near-ultraviolet radiation and configured to re-emit light in a yellow, orange or red spectral range.

### TECHNICAL FIELD

A method for producing a light-emitting semiconductor device is provided. A light-emitting semiconductor device is also provided.

### BACKGROUND

U.S. Publication No. 2012/0132945 A1 refers to LED chips comprising a conversion element based on conversion layers.

International Publication No. WO 2018/095816 A1 is drawn to a manufacturing method for LED chips.

In “Phosphor-Free White Light From InGaN Blue and Green Light-Emitting Diode Chips Covered With Semiconductor-Conversion AIGaInP Epilayer” by Ray-Hua Horng et al., in IEEE Photonics Technology Letters, volume 20, issue 13, pages 1139 to 1141, 2008, a semiconductor based conversion element is described.

### SUMMARY

Embodiments provide an efficient method for producing a light-emitting semiconductor device which is capable of emitting spectral narrowband colored light.

In e, thin-film multiple quantum well stacks, mQWs for short, are used as a semiconductor wavelength converter. The stacks are of InₓGa_{1-x-y}Al_{y}P, wherein 0≤x≤1 and 0≤y≤1, InGaAlP for short. The mQW structure is preferably used as a blue-pumped optical converter in light-emitting diodes, LEDs for short. Particularly, the wavelength converter mQW structure is epitaxially grown on a different substrate compared to the process of preparing InGaAlP electroluminescent LED devices of essentially the same material.

According to at least one embodiment, the method is designed for producing light-emitting semiconductor devices. These light-emitting semiconductor devices can be LEDs.

According to at least one embodiment, the method comprises the steps of providing a growth substrate. The growth substrate is transmissive for visible light. This means that the growth substrate does not significantly absorb light in the spectral range between 420 nm and 700 nm, preferably between 400 nm and 750 nm. In particular, a transmission coefficient of the growth substrate in said spectral range is at least 80% or 90% or 95% or 98% at all wavelengths.

According to at least one embodiment, the method comprises the steps of growing a semiconductor layer sequence onto the growth substrate. The growth is preferably an epitaxial growth, for example, by means of metalorganic vapor-phase epitaxy, MOVPE for short, or metalorganic chemical vapor deposition, MOCVD for short.

According to at least one embodiment, the semiconductor layer sequence is based on InₓGa_{1-x-y}Al_{y}P, wherein 0≤x≤1 and 0≤y≤1, or 0<x <1 and 0<y<1. Preferably, the semiconductor layer sequence comprises Ga, In and P and optionally also Al. The semiconductor layer sequence includes a plurality of layers that can have different material compositions within the InₓGa_{1-x-y}Al_{y}P system, that is, x and y can be different for the layers of the semiconductor layer sequence.

As an alternative to InₓGa_{1-x-y}Al_{y}P, the semiconductor layer sequence may also be based on AlₙIn₁₋ₙ₋ₘGaₘN or AlₙIn₁₋ₙ₋ₘGaₘAs, wherein 0≤n≤1, 0≤m≤1 and n+m≤1.

The semiconductor layer sequence may comprise dopants and additional constituents. For simplicity's sake, however, only the essential constituents of the crystal lattice of the semiconductor layer sequence are indicated, that is Al, As, Ga, In, N or P, even if these may in part be replaced and/or supplemented by small quantities of further substances.

According to at least one embodiment, the semiconductor layer sequence comprises a multi-quantum well structure which is configured to absorb blue light and/or near-ultraviolet radiation. Further, the multi-quantum well structure is configured to re-emit light in the green, yellow, orange or red spectral range that is generated from the absorbed blue light or near-ultraviolet radiation by means of photoluminescence. All of a primary radiation, that is, of the blue light and/or of the near-ultraviolet radiation, can be used to produce the green, yellow, orange or red light, or only part of the primary radiation is used for this purpose in order to emit mixed light still comprising some of the primary radiation. The mixed light is white light, for example.

In at least one embodiment, the method is designed for producing a light-emitting semiconductor device and comprises the steps of:

A) providing a growth substrate that is transmissive for visible light, and

B) growing a semiconductor layer sequence onto the growth substrate,

wherein the semiconductor layer sequence is based on InGaAlP and comprises a multi-quantum well structure configured to absorb blue light or near-ultraviolet radiation and to re-emit light in the green, yellow, orange or red spectral range.

Next generation optical converters that are not based on rare earth-element emission and capable of providing fast, linear output at increasing pump flux levels could likely be found in pseudobinary (ternary) and/or pseudoternary (quaternary) alloys of relatively narrow band gap (BG or Eg for short) semiconductor materials. This approach on the one hand relies on volumes of research results on semiconductor materials and information on tuning their minimum band gap and other properties depending on Vegard's law. On the other hand, no electrically pumped structures, but only optical excitation is needed. This proviso relaxes some of the stringent requirements on electronic properties like charge carrier mobility or doping for different conductivity types and related factors shown to influence LED performance like current crowding, inhomogeneous population of, and leakage from, the recombination region, and may actually remove long-term degradation issues, improving life-time.

While the purity of such materials largely determines their performance, preparing structures for electrical excitation is harder than for sole optical pumping. Non-radiative recombination that kills the near-band edge (NBE for short) emission in LEDs has its probability proportional to concentration of deep level impurities, so-called Schockley-Read-Hall losses, and may arise also due to Auger-like recombination processes. The latter has to be considered in the structural design of the converter.

Preferably, the optically pumped multiple quantum well structure comprises alternating layers of absorbing and emitting materials, enclosed by an in-coupling window of larger band gap material capable of transmitting the pump light and a smaller gap material residual absorber for out-coupling. This arrangement forms essentially the multi-layer quantum well structure which is fed by electron and hole pairs created by the irradiation absorbed in the absorbing layers of slightly larger energy gap which are still capable of absorbing the pump radiation.

Electrons and holes preferentially recombine in the lower band gap wells where photons are created and exit thereafter through the optional output absorber. The latter removes any residual pump light that might affect the output spectrum but not the multi-quantum well emission. The absorbers should be located within a diffusion length of the charge carriers generated by the absorbed radiation to the photoluminescent quantum well layers and by virtue of their band gap exceeding that of the wells should ensure sufficient carrier confinement in the latter; thus, the emitting quantum well layers should be close to the absorbers. A quantum well characteristic thickness of 2 nm to 4 nm inclusive allows for low re-absorption of the emitted light in that layer.

The high refractive index (RI) in such converters may require surface structuring of the out-coupler for light extraction, in order to minimize total internal reflection losses. Such a structuring could be a roughening created by wet or reactive ion etching, but could also be formed by added structured layers of lower or graded refractive indices. It may be also possible to add other light manipulation layers based on periodic or aperiodic nano-structuring with a refractive index contrast like photonic lattices.

One interest of searching for such near-band edge emitters is to find alternatives to conventional phosphors for the yellow-orange-red spectral region. Combining binary materials whose band gap values lie near or inside the visible spectral range, that is from red to violet or near-ultraviolet, e. g. between 1.6 eV to 3.3 eV inclusive, allows for engineering of alloys with a band edge in the desired spectral range. Such materials contain both insulators and compound semiconductors that are based on group IV, V and VI elements like silicides and carbides (Si, C), antimonides (Sb), arsenides (As), phosphides (P), nitrides (N), tellurides (Te), selenides (Se), sulfides (S) and oxides (0). Direct gap materials are preferred over indirect band gap ones.

Here, an example is presented using one of the most popular combinations for the visible LED industry, that is phosphides of Al, Ga and In, which show excellent emitting properties in the red and infrared spectral range. This material can be well tuned across the visible spectral range by band gaps of 2.45 eV (AlP, indirect band gap), 2.26 eV (GaP, indirect band gap) and 1.35 eV (InP, direct band gap). AlGaP if efficient in particular in the spectral range from 510 nm to 550 nm (indirect band gap) for green electroluminescent emission and AlGaInP in the spectral range from 560 nm to 650 nm (indirect/direct band gap).

InGaAlP is currently not used as a photoluminescent material in LEDs but is used as an electroluminescent material. However, there is a strong interest in finding novel narrow band red emitters using photon excitation.

Typically, InGaAlP quantum wells are deposited on GaAs substrates for red electroluminescence. The layers of the semiconductor layer sequence are deposited by various thin film vacuum deposition techniques like MOCVD and MBE. In order to use this stack as a phosphor, GaAs must be removed to transmit the emission wavelengths of InGaAlP after blue LED excitation. Otherwise, GaAs will absorb all the visible light because of its small band gap of about 1.4 eV.

InGaAlP is an efficient photoluminescent material and is well known from its widespread use as an electroluminescent material emitting in the red spectral range. InGaAlP could be bonded to glass or sapphire followed by removal of GaAs by chemomechanical polishing, etching or the like.

The general advantages of thin film mQW converters as described here over a conventional, encapsulated powder phosphor approach are in particular:

i) High radiative recombination rates of near-band gap emission to minimize output saturation at high excitation fluxes;

ii) continuous peak wavelength and spectral profile tuning for color and luminous efficacy control by the material selection and by the design of the multi-quantum well structure and of absorber layers;

iii) spectrally narrow emission, typically between 15 nm to 30 nm from semiconductor alloys compared to 60 nm to 90 nm from conventional phosphors, for a wide, saturated color gamut that is preferred in projection or display backlighting, and mitigates the need for lossy filtering of broad phosphor emissions;

iv) reduced losses for the pump light and converted radiation due to absence of backscattering centers;

v) well-proven epitaxy deposition methods that allow for high-purity, finely tunable structures to be created, as opposed to typical solid state reaction methods for preparing phosphors, potentially requiring milling/sieving/washing, with instabilities in color binning yield;

vi) use of transparent oxide substrates that enables excitation and emission wavelengths for transmission of light in the visible region;

vii) due to a reasonably close lattice match, the transmissive substrates according to the present method allow epitaxial growth of InGaAlP multiple quantum wells in a similar manner to that of GaAs;

viii) transparent substrates such as YSZ (with or without CeO₂ buffer (intermediate) layer on it), r- or c-cut sapphire with CeO₂ buffer (intermediate) layer, Gd₃Ga₅O₁₂ (GGG for short), Y₃Al₅O₁₂ (YAG for short), or orthorhombic SrLaGaO₄ could be used because of their lattice parameter properties close to InGaAlP;

ix) no necessity of removing the growth substrate since it is transparent in the visible region; also, the thermal contact between epitaxy and its substrate is far better than for layers glued on a new transparent substrate which is important for removal of the heat caused by conversion losses which arise from the finite quantum efficiency and the Stokes shift when down-converting from the optical pump wavelength (e.g., blue) to the emission wavelength (e.g., red); and

x) InGaAlP is an inorganic material and, hence, thermally stable compared with other partly or fully organic narrow band emitters such as quantum dots which are often hybrids of a semiconductor material with organic ligands or conjugated polymers.

According to at least one embodiment, the method further comprises a step A1) between method steps A) and B). In step A1), an intermediate (buffer) layer is grown onto the growth substrate, preferably directly onto the growth substrate. A thickness of the intermediate layer is preferably at least 10 nm or 50 nm or 100 nm and/or at most 0.5 μm or 1 μm. The intermediate layer can cover the whole growth substrate, in particular with a constant thickness.

According to at least one embodiment, the semiconductor layer sequence is grown onto the intermediate layer, in particular directly onto the intermediate layer.

According to at least one embodiment, the intermediate layer is of a different material system than the semiconductor layer sequence and/or the growth substrate. That is, the intermediate layer can have a different crystal lattice than the semiconductor layer sequence and/or the growth substrate. For example, a lattice constant of the intermediate layer is between lattice constants of the semiconductor layer sequence and of the growth substrate, acting as a “buffer” against the lattice constant mismatch.

According to at least one embodiment, the growth substrate comprises at least one of oxygen, aluminum, gallium, yttrium, lanthanum, gadolinium, strontium and zirconium. For example, the growth substrate is of partially or completely yttria-stabilized zirconia.

According to at least one embodiment, the intermediate layer is an oxide layer. In particular, the intermediate layer is of a metal oxide. The intermediate layer may comprise or consist of an oxide of at least one of Ce, Y, Nd, La, Tb, Ho, Tm, Yb, Hf, Zr, V. Preferably, the intermediate layer is of cerium oxide.

According to at least one embodiment, the growth substrate is a sapphire substrate. A growth surface of the growth substrate is then preferably of r-sapphire or of c-sapphire. In this case, there can be the intermediate layer which is preferably of cerium oxide.

According to at least one embodiment, the growth substrate comprises at least one of (Gd,Y)₃(Al,Ga)₅O₁₂ and preferably orthorhombic (Sr,Ba,Ca)La(Al,Ga)O₄ or consists thereof.

In short, an InGaAlP multi-quantum well stack is grown on a transparent substrate such as yttria-stabilized ZrO₂ (YSZ for short) instead of being grown onto a GaAs substrate that absorbs visible light. As an alternative, the InGaAlP semiconductor layer sequence is grown on an intermediate layer of CeO₂ on r-sapphire or on c-sapphire templates. As a further possibility, the InGaAlP material is grown on garnets like Gd₃Ga₅O₁₂ (GGG for short), Y₃Al₅O₁₂ (YAG for short), or on an orthorhombic material like SrLaGaO₄ because of its lattice parameter properties.

According to at least one embodiment, the semiconductor layer sequence is grown with one or two cladding layer(s). Preferably, a first cladding layer is located at a side of the multi-quantum well structure facing the growth substrate. A second cladding layer may be located at a side of the multi-quantum well structure remote from the growth substrate. The first and/or the second cladding layer can be transmissive to visible light or at least to the radiation generated in the multi-quantum well structure.

According to at least one embodiment, the multi-quantum well structure comprises a plurality of emission layers and a plurality of absorption layers. The absorption layers are configured to absorb the blue light or the near-ultraviolet radiation, and the emission layers have a smaller band gap than the absorption layers and are configured to re-emit the green, yellow, orange or red light.

The emission layers and the absorption layers are stacked one above the other, preferably in an alternating manner. Adjacent emission layers and absorption layers may follow one another directly or indirectly with interposed layers. All emission layers and/or absorption layers may be of the same design or may have different configuration, for example, to emit light of various peak wavelengths.

According to at least one embodiment, the multi-quantum well structure further comprises a plurality of barrier layers. The barrier layers may be arranged between adjacent emission layers only in such a manner that there is no barrier layer between emission layers and the assigned absorption layers. Otherwise, the barrier layers may be located between adjacent quantum well layers, irrespective of their type.

According to at least one embodiment, a distance between adjacent absorption layers and emission layers is at most 4 nm or 2 nm or 1 nm. Thus, each one of the absorption layers can be located close to the assigned emission layer. A thickness of the absorption layers and/or of the associated emission layers is at least 1 nm or 2 nm and/or at most 10 nm or 5 nm or 3 nm, for example. The absorption layers may have a thickness different from a thickness of the emission layers.

According to at least one embodiment, the semiconductor layer sequence is grown with a filter layer. The filter layer can be located at a side of the quantum well structure remote from the growth substrate. As an alternative, the filter layer is grown at a side of the quantum well structure facing the growth substrate. The filter layer is opaque for the blue light and/or the near-ultraviolet radiation. Thus, by means of the filter layer it can be avoided that primary or pump radiation that has entered the semiconductor light conversion device can leave said finished light-emitting semiconductor device. The filter layer may be another and/or additional and/or thicker absorber material layer that does the job of blocking final pump photons.

According to at least one embodiment, the semiconductor layer sequence is provided with at least one of a roughening and a coupling-out layer. By means of such structures and/or layers, a coupling-out efficiency can be increased. The coupling-out layer is an antireflection layer, for example.

According to at least one embodiment, the intermediate layer is grown at a substrate temperature of at least 500° C. or 600° C. and/or of at most 800° C. or 900° C. During growth of the intermediate layer, an oxygen pressure layer may be at most 0.5 bar or 0.1 bar or 1 mbar. As an alternative or in addition, said oxygen pressure is at least 10⁻⁷ bar or 10⁻⁵ bar or 1 mbar.

According to at least one embodiment, the method further comprises a step C) following step B). In step B), a light-emitting diode chip for producing the blue light or the near-ultraviolet radiation is provided. At least one of the semiconductor layer sequence and the growth substrate are attached to the light-emitting diode chip. The light-emitting diode chip is preferably based on AlInGaN. The light-emitting diode chip may be a sapphire-InGaN or thin-film InGaN LED-chip. The LED chip is preferably a face-emitter, but could also be an edge-emitter.

According to at least one embodiment, a light-transmissive adhesive is used to attach the semiconductor layer sequence and/or the growth substrate to the light-emitting diode chip. The adhesive is preferably a glue based on a polymer like a silicone or a silicone-epoxide hybrid material. The adhesive can be thin, in particular with a thickness or a mean thickness of at most 10 μm or 3 μm or 1 μm and/or of at most 10 nm or 0.1 μm. As an alternative to an adhesive, bonding methods like anodic or atomic diffusion bonding may also be applied.

According to at least one embodiment, the semiconductor layer sequence is located on a side of the growth substrate remote from the light-emitting diode chip. As an alternative, the semiconductor layer sequence is located on a side of the growth substrate facing the light-emitting diode chip. Thus, the adhesive can be at the side of the growth substrate or at the side of the semiconductor layer sequence.

According to at least one embodiment, the method further comprises a step D) following step C). In step D), the growth substrate is removed from the semiconductor layer sequence and optionally from the light-emitting diode chip. In this case, the adhesive is preferably located directly between the light-emitting diode chip and the semiconductor layer sequence.

According to at least one embodiment, the intermediate layer remains partially or completely at the semiconductor layer sequence so that in step D) only the growth substrate is removed but not the intermediate layer. Thus, the intermediate layer can be still present in the finished light-emitting semiconductor device. For example, the roughening is formed in the intermediate layer, wherein the roughening can be limited to the intermediate layer or can reach through the intermediate layer.

According to at least one embodiment, the semiconductor layer sequence is a photoluminescent wavelength conversion element or is an essential part thereof. In particular, the semiconductor layer sequence does not have any electrical function in the finished light-emitting semiconductor device but only an optical function. Especially, no current is fed through a material of the wavelength conversion element. If the growth substrate is still present in the wavelength conversion element, the wavelength conversion element can be mechanically self-supporting so that no additional carrier is required for the wavelength conversion element.

In further embodiments a light-emitting semiconductor device is additionally provided. The light-emitting semiconductor device is manufactured with at least one embodiment of the method as stated above. Features of the light-emitting semiconductor device are therefore also disclosed for the method and vice versa.

In at least one embodiment, the light-emitting semiconductor device comprises the light-emitting diode chip and the semiconductor layer sequence which is based on InGaAlP and which comprises the multi-quantum well structure as the photoluminescent wavelength conversion element. In operation of the light-emitting diode chip, the blue light or the near-ultraviolet radiation is produced and is at least partially converted to the re-emitted green, yellow, orange or red light in the multi-quantum well structure of the semiconductor layer sequence. Preferably, the light-emitting semiconductor device comprises the growth substrate, too.

### BRIEF DESCRIPTION OF THE DRAWINGS

A method and a light-emitting semiconductor device described herein are explained in greater detail below by way of exemplary embodiments with reference to the drawings. Elements which are the same in the individual figures are indicated with the same reference signs. The relationships between the elements are not shown to scale, however, but rather individual elements may be shown exaggeratedly large to assist in understanding.

In the figures:

FIGS. 1 to 6 show schematic sectional representations of method steps to produce an exemplary embodiment of a light-emitting semiconductor device;

FIGS. 7 to 10 show schematic sectional representations of light-emitting semiconductor devices;

FIGS. 11 to 13 show schematic sectional representations of semiconductor layer sequences for exemplary embodiments of light-emitting semiconductor devices;

FIGS. 14 and 15 show schematic sectional representations of method steps to produce an exemplary embodiment of a light-emitting semiconductor device; and

FIGS. 16 to 18 show schematic sectional representations of method steps to produce a modification of a light-emitting semiconductor device.

### DETAILED DESCRIPTION OF ILLUSTRATIVE EMBODIMENTS

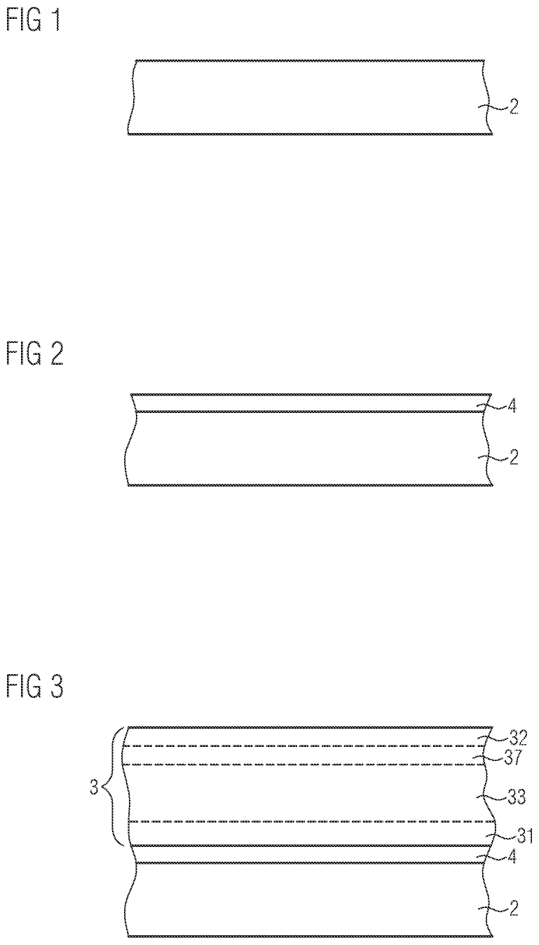

In FIGS. 1 to 6, an exemplary method for producing light-emitting semiconductor devices 1 is illustrated. According to FIG. 1, a growth substrate 2 is provided. The growth substrate 2 is transmissive for visible radiation. According to FIG. 2, in an optional step an intermediate layer 4 is applied to the growth substrate 2.

In the method step of FIG. 3, a semiconductor layer sequence 3 is grown onto the intermediate layer 4. The semiconductor layer sequence 3 comprises a multi-quantum well structure 33, which is preferably arranged between a first cladding layer 31 and a second cladding layer 32. As an option, there could be a filter layer 37. The semiconductor layer sequence 3 is based on InₓGa_{1-x-y}Al_{y}P, InGaAlP for short, wherein 0≤x≤1 and 0≤y≤1.

Preferably, the growth substrate 2 is of YSZ (yttria-stabilized zirconium) and the intermediate layer 4 is of cerium oxide. Cubic CeO₂ (lattice parameter a=5.42 Å) could epitaxially be grown on YSZ with a lattice mismatch of 5.8%. Thus, CeO₂/YSZ could be used as a template for the growth of InₓGa_{1-x-y}Al_{y}P compositions (InGaAlP for short). The lattice mismatch between InGaAlP (with a lattice parameter a=5.6 Å at a composition of In_{0.49}Ga_{0.51}P) and CeO₂ is then 4.2%.

It is also possible to grow epitaxial CeO₂ on r-sapphire. This is an alternative to CeO₂/YSZ or YSZ. Further, epitaxial growth of CeO₂ on off-cut c-sapphire or also r-cut sapphire could also be used as a template for subsequent InGaAlP growth. Yttria-stabilized Zirconia as the growth substrate 2 would have a lattice parameter a=5.12 Å. Considering a lattice parameter of ˜5.65 Å for In_{0.49}Ga_{0.51}P composition which emits in the red spectral range around 650 nm, the lattice mismatch will be 9.3%. The lattice mismatch decreases with more Ga and hence by tuning the composition towards orange.

The lattice dimensions could be further varied by changing the composition of the cladding layers 31, 32, which are preferably of In_{0.5}Ga_{0.5-x}AlₓP, wherein 0<x<0.5, to match with the substrates 2 proposed here. The lattice mismatch could also be overcome if a 111 plane, that is a diagonal plane of a cubic YSZ, triangular plane, is used for growth of InGaAlP.

The epitaxial CeO₂ thin film intermediate layer 4 is thus grown on YSZ or on r-sapphire by a physical vapor deposition technique. The substrate temperature was varied between 500° C. and 800° C. The oxygen pressure was varied between 1×10⁻⁵ Torr and 400 Torr during the deposition. The thickness of the CeO₂ is between 10 nm and 500 nm. The InGaAlP multi-quantum well structure 33 could be grown using MOCVD using standard growth parameters as known from electroluminescent LEDs.

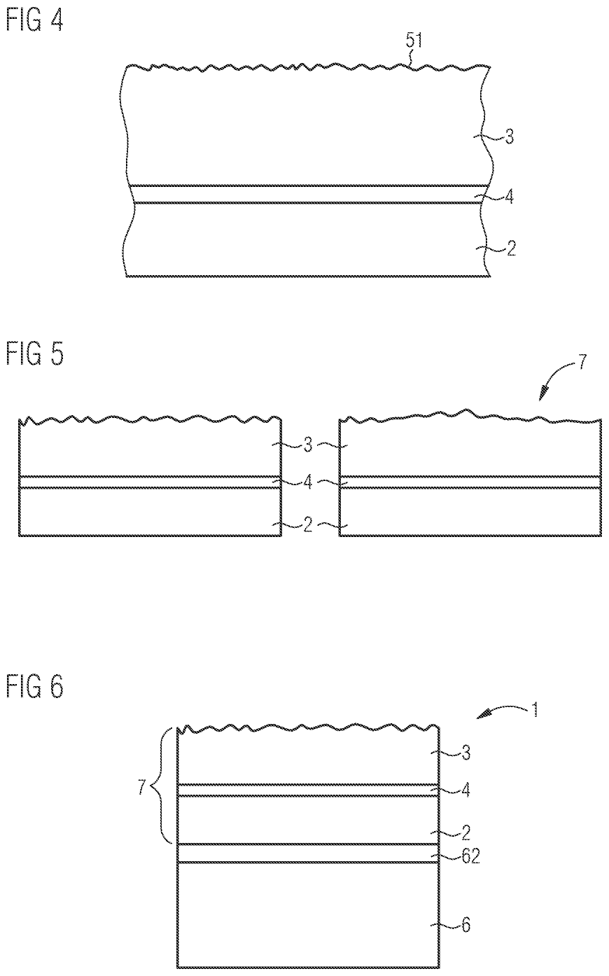

In the optional step of FIG. 4, a roughening 51 is created in the semiconductor layer sequence 3. The optional roughening 51 is to increase a coupling-out efficiency of the finished device 1.

According to the optional step of FIG. 5, the growth substrate 2 together with the intermediate layer 4 and the semiconductor layer sequence 3 are singulated to conversion elements 7. Thus, the components for the conversion elements 7 could be produced in a wafer assembly and singulation to the size of individual LED chips, for example, could take place comparably late in the method.

In FIG. 6 it is shown that a light-emitting diode chip 6 is provided. The conversion element 7 is attached to the light-emitting diode chip 6 by means of an adhesive 62, which is a silicone-based glue, for example. As an alternative to polymers like silicones or siloxanes or the adhesive 62, low temperature melting point glasses could also be used. In a lateral direction, the conversion element 7 and the light-emitting diode chip 6 could have the same size.

Thus, after epitaxial thin film growth of the InGaAIP multi-quantum well structure 3, 33 on the transparent templates/substrates 2, this stack 3, 33 is attached to the emitting surface of the InGaN blue LED chip 6 for blue excitation of the InGaAIP multi-quantum well structure 3, 33 in order to produce secondary radiation like yellow, orange or red light.

If desired, YSZ or sapphire substrates could also be detached at the interface of CeO₂ and YSZ substrate 2 by laser lift-off, for example. CeO₂ could be an efficient sacrificial layer for laser lift-off methods.

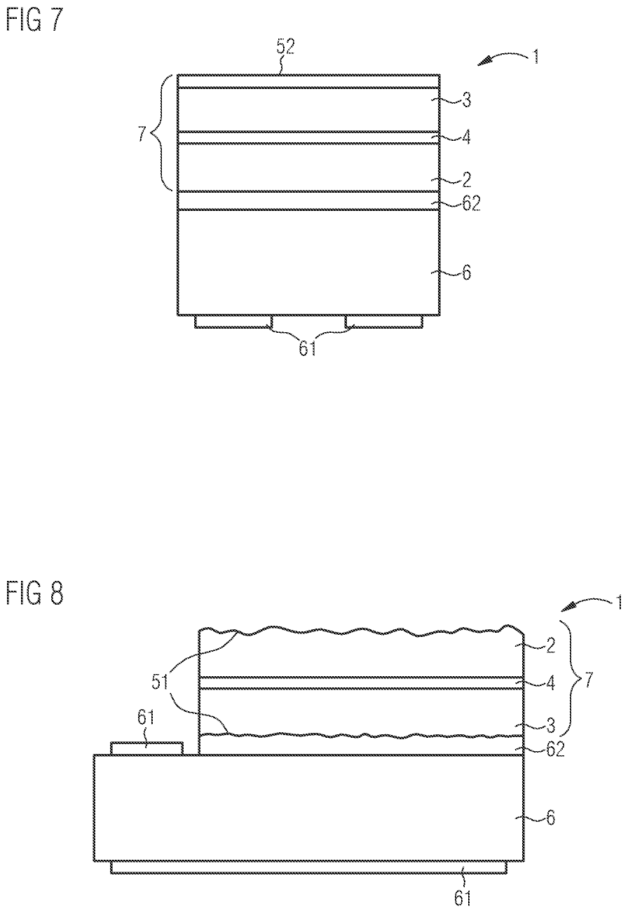

According to FIG. 7, the conversion element 7 is provided with a coupling-out layer 52. The coupling-out layer 52 could be an antireflection layer, for example, with a thickness of λ/4n or of a graded refractive index material. Herein, λ denotes the wavelength of maximum intensity of the light generated in the conversion element 7 and n denotes the refractive index of the coupling-out layer 52 at this wavelength. The coupling-out layer 52 may be combined with the filter layer, not shown.

Moreover, according to FIG. 7, metallic electric contact layers 61 for electrically contacting the device 1 are located on a bottom side of the light-emitting diode chip 6, the bottom side facing away from the conversion element 7. Thus, the conversion element 7 does not have any electrical function.

In the exemplary embodiment of FIG. 8, the metallic electric contact layers 61 are located on both main sides of the light-emitting diode chip 6. To enable accessing the electric contact layer 61 on the top side of the light-emitting diode chip 6, the conversion element 7 may have a cutout. A corresponding configuration is also possible in all other exemplary embodiments.

Further, according to FIG. 8, the semiconductor layer sequence 3 faces the light-emitting diode chip 6 and not the growth substrate 2. This configuration could be used in all other exemplary embodiments, too.

To enable an improved coupling-in and also coupling-out of light, the conversion element 7 can be provided with the roughening 51 on both main sides as is also possible in all other exemplary embodiments.

In the embodiment of FIG. 9, the conversion element 7 is free of the growth substrate, which has been removed with laser lift-off, for example. The optional roughening 51 could be limited to the intermediate layer 4. Contrary to what is shown, the roughening 51 may proceed into the semiconductor layer sequence 3.

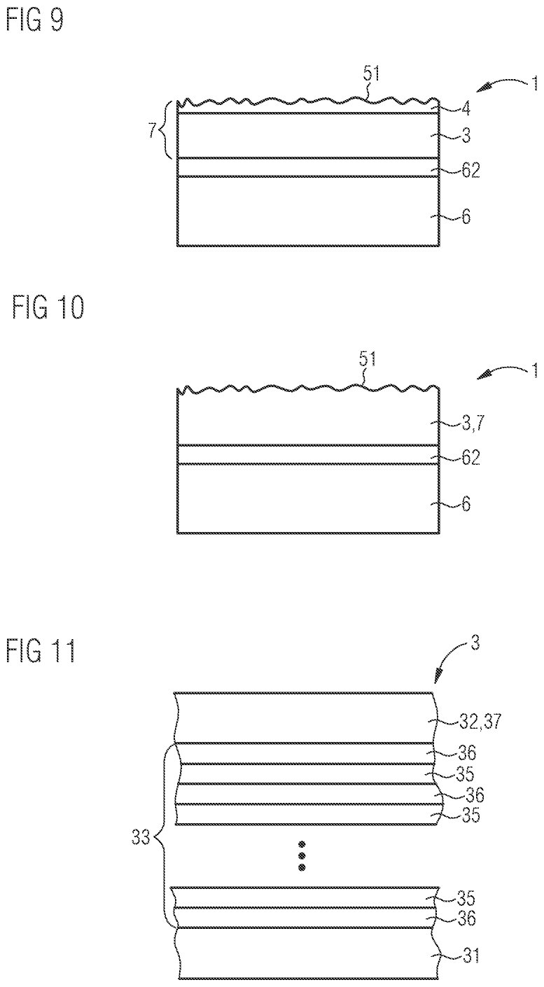

The device 1 of FIG. 10 is free of both the growth substrate and the intermediate layer. Thus, the optional roughening 51 could be produced directly in the semiconductor layer sequence 3.

FIGS. 11 to 13 illustrate different possibilities to configure the semiconductor layer sequence 3. These configurations could be used in each one of the exemplary embodiments of FIGS. 1 to 10.

According to FIG. ii, the multi-quantum well structure 33 is composed only of absorption layers 35 to absorb blue light and of emitting layers 36. Charge carriers generated by the absorption of primary radiation in the absorption layers 35 are transferred to the emitting layers 36, in which visible light is produced by charge carrier recombination. A band gap of the emitting layers 36 is slightly smaller than for the absorption layers 35 so that both the absorption layers 35 and the emission layers 36 work in the near-band gap regime. That is, the absorption layers 35 only absorb the primary radiation from the light-emitting diode chip but not the secondary radiation from the emission layers 36. Preferably, the multi-quantum well structure 33 begins and ends with one of the emission layers 36.

As an option, the second cladding layer 32 could at the same time form the filter layer 37. The optional filter layer 37 is designed to absorb pump light penetrating through the multi-quantum well structure 33, so that no pump light leaves the device 1.

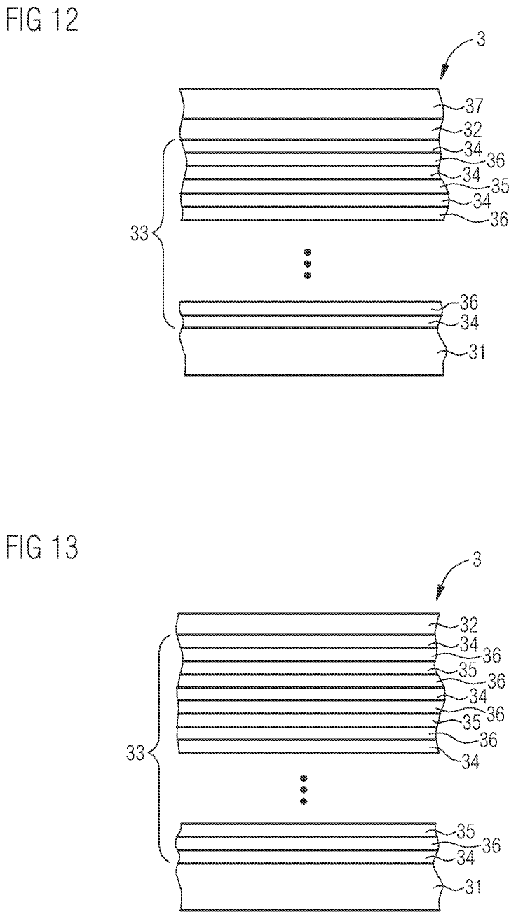

In FIG. 12, the configuration of the multi-quantum well structure 33 is more complex. In addition, there are barrier layers 34. The barrier layers 34 have a comparably large band gap and are transparent to the primary and the secondary radiation. Between adjacent absorption layers 35 and emission layers 36, there is in each case one of the barrier layers 34.

Thus, the repeating layer sequence in the multi-quantum well structure 33 is barrier layer—emission layer—barrier layer—absorption layer and so on.

As an option, the second cladding layer 32 and the filter layer 37 could be realized by two separate layers. For example, the second cladding layer 32 is arranged closer to the multi-quantum well structure 33 than the filter layer 37.

In FIG. 13, the multi-quantum well structure 33 comprises less barrier layers than in FIG. 12. Thus, there are barrier layers 34 only between adjacent emission layers 36 but not between the respective emission layer 36 and the assigned absorption layer 35. Thus, the repeating layer sequence in the multi-quantum well structure 33 is barrier layer—emission layer—absorption layer—emission layer and so on.

A thickness of the barrier layers 34, of the emission layers 36 and of the absorption layers 35 is preferably between 2 nm and 4 nm.

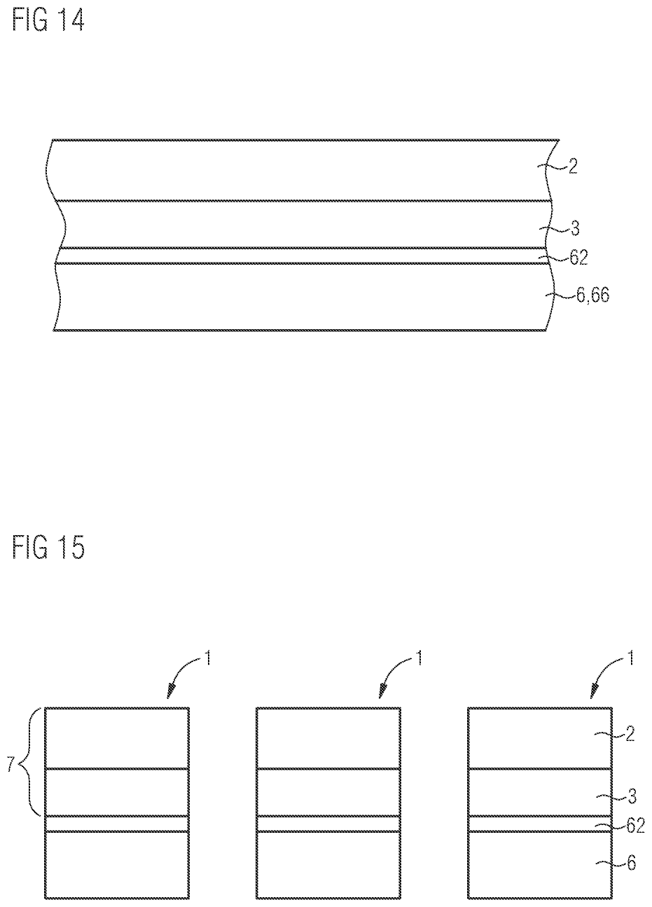

FIGS. 14 and 15 illustrate a sequence of method steps alternative to FIGS. 5 and 6. According to FIG. 14, the light-emitting diode chips 6 are provided as a wafer 66 as well as the growth substrate 2 with the semiconductor layer sequence 2. Hence, a connection between the light-emitting diode chips 6, 66 and the growth substrate 2 with the semiconductor layer sequence 2 by means of the adhesive 62 is established in the wafer assembly.

In a subsequent step, both the diode chips 6, 66 and the growth substrate 2 with the semiconductor layer sequence 2 are singulated to the light-emitting semiconductor device 1. A corresponding manufacture in the wafer assembly is possible in the production of the other exemplary devices 1, too.

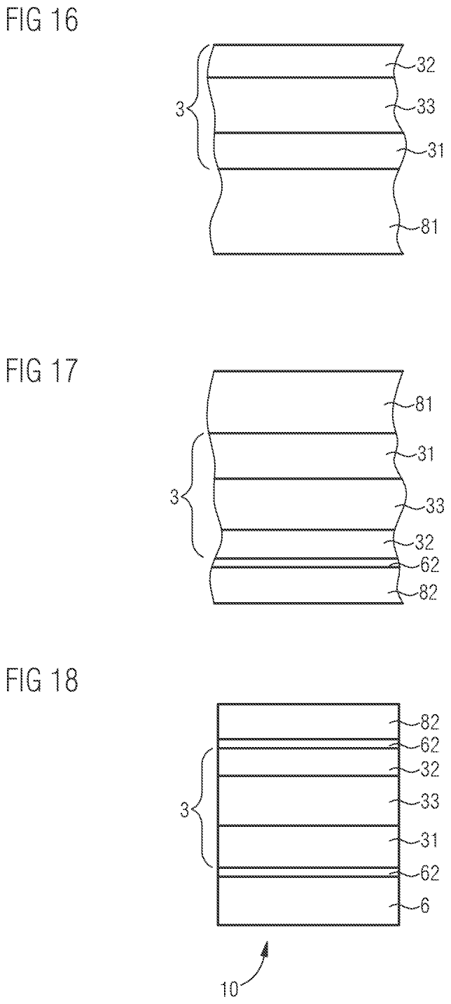

In FIGS. 16 to 18, a modified method is illustrated. In the step of FIG. 16, the semiconductor layer sequence 3 is grown on an opaque GaAs growth substrate 81. Subsequently, see FIG. 17, a light-transmissive replacement substrate 82 is attached by means of the adhesive 62. The replacement substrate 82 is of glass or sapphire, for example. Afterwards, the opaque growth substrate 81 is removed and the light-emitting diode chip 6 is attached to the replacement substrate 82 or to the semiconductor layer sequence by means of the adhesive 62.

Contrary to what is required in FIGS. 16 to 18, in the method described here no opaque GaAs growth substrate 81 is needed. Thus, the number of transfer steps and of adhesive layers 62 can be reduced, which results in decreased process time and in increased thermal connection of the conversion element.

The invention described here is not restricted by the description given with reference to the exemplary embodiments. Rather, the invention encompasses any novel feature and any combination of features, including in particular any combination of features in the claims, even if this feature or this combination is not itself explicitly indicated in the claims or exemplary embodiments.

What is claimed is:

1. A method for producing a light-emitting semiconductor device, the method comprising:
providing a growth substrate that is transmissive for visible light; and
growing a semiconductor layer sequence on the growth substrate,
wherein the semiconductor layer sequence is based on InGaAlP, and
wherein the semiconductor layer sequence comprises a multi-quantum well structure configured to absorb blue light or near-ultraviolet radiation and configured to re-emit light in a yellow, orange or red spectral range.

2. The method according to claim 1, further comprising growing an intermediate layer on the growth substrate before growing the semiconductor layer sequence, wherein the intermediate layer is of a different material system than the semiconductor layer sequence and the growth substrate.

3. The method according to claim 2, wherein the growth substrate comprises at least one of aluminum, gallium, yttrium, lanthanum, gadolinium, strontium or zirconium, and wherein the intermediate layer is an epitaxial oxide layer.

4. The method according to claim 2, wherein the growth substrate is of yttria-stabilized zirconia, and wherein the intermediate layer is of cerium oxide.

5. The method according to claim 2, wherein the growth substrate has a growth surface of r-sapphire or of c-sapphire, and wherein the intermediate layer is of cerium oxide.

6. The method according to claim 1, wherein the growth substrate comprises at least one of (Gd,Y)₃(Al,Ga)₅O₁₂ or (Sr,Ba,Ca)La(Al,Ga)O₄.

7. The method according to claim 1, wherein the semiconductor layer sequence is grown with a cladding layer at a side of the multi-quantum well structure facing the growth substrate, and wherein the cladding layer is transmissive for visible light.

8. The method according to claim 1,
wherein the multi-quantum well structure comprises a plurality of emission layers and of absorption layers arranged alternatingly, and
wherein the absorption layers are configured to absorb the blue light or the near-ultraviolet radiation, and the emission layers have a smaller band gap than the absorption layers and are configured to re-emit yellow, orange or red light.

9. The method according to claim 8,
wherein the multi-quantum well structure further comprises a plurality of barrier layers,
wherein the barrier layers are arranged between adjacent absorption layers and the associated emission layers,
wherein a distance between adjacent absorption layers and emission layers is at most 4 nm, and
wherein a thickness of the absorption layers and of the associated emission layers is between 1 nm and 5 nm inclusive.

10. The method according to claim 1,
wherein the semiconductor layer sequence is grown with a filter layer, and
wherein the filter layer is located at a side of the quantum well structure remote from the growth substrate, the filter layer being opaque for the blue light or the near-ultraviolet radiation.

11. The method according to claim 1, wherein the semiconductor layer sequence comprises at least one of a roughening and a coupling-out layer.

12. The method according to claim 2,
wherein the intermediate layer is grown at a substrate temperature between 500° C. and 800° C. inclusive,
wherein the intermediate layer is grown with a thickness of between 10 nm and 500 nm, and
wherein an oxygen pressure while growing the intermediate layer is at most 0.5 bar.

13. The method according to claim 2, further comprising providing a light-emitting diode chip for producing the blue light or the near-ultraviolet radiation, wherein at least one of the semiconductor layer sequence or the growth substrate are attached to the light-emitting diode chip.

14. The method according to claim 13, using a light-transmissive adhesive to attach the semiconductor layer sequence and the growth substrate to the light-emitting diode chip, wherein the semiconductor layer sequence is located on a side of the growth substrate remote from the light-emitting diode chip.

15. The method according to claim 13, further comprising removing the growth substrate from the semiconductor layer sequence and from the light-emitting diode chip.

16. The method according to claim 15, wherein the intermediate layer at least partially remains at the semiconductor layer sequence so that only the growth substrate is removed but not the intermediate layer.

17. The method according to claim 13, wherein the semiconductor layer sequence is a photoluminescent wavelength conversion element that does not have any electrical function in the light-emitting semiconductor device.

18. A light-emitting semiconductor device produced with the method of claim 17, the light-emitting semiconductor comprising:
the light-emitting diode chip; and
the semiconductor layer sequence based on InGaA1P with the multi-quantum well structure as a photoluminescent wavelength conversion element,
wherein in operation of the light-emitting diode chip the blue light or the near-ultraviolet radiation is produced and is at least partially converted to the re-emitted yellow, orange or red light.
